(19) United States
(12) Patent Application Publication
(10) Pub. No.: US 2024/0321956 A1
(43) Pub. Date: Sep. 26, 2024

(54) INTEGRATED CIRCUIT DEVICE

(71) Applicant: SAMSUNG ELECTRONICS CO., LTD., Suwon-si (KR)

(72) Inventors: Woosuk Choi, Suwon-si (KR); Beomjin Park, Suwon-si (KR); Myunggil Kang, Suwon-si (KR); Dongwon Kim, Suwon-si (KR); Hyumin Yoo, Suwon-si (KR); Soojin Jeong, Suwon-si (KR)

(21) Appl. No.: 18/614,804

(22) Filed: Mar. 25, 2024

(30) Foreign Application Priority Data
Mar. 24, 2023 (KR) 10-2023-0039170
May 11, 2023 (KR) 10-2023-0061261

(51) Int. Cl. H01L 29/06; H01L 27/088; H01L 29/08; H01L 29/423; H01L 29/66; H01L 29/775; H01L 29/786

(52) U.S. Cl. CPC H01L 29/0665; H01L 27/088; H01L 29/0847; H01L 29/42392; H01L 29/66439; H01L 29/66545; H01L 29/66553; H01L 29/775; H01L 29/78696

(57) ABSTRACT

An integrated circuit device includes a fin-type active region that protrudes from a substrate and extends in a first horizontal direction, a plurality of nanosheets disposed on the fin-type active region and separated from each other in the vertical direction, a gate line that extends in a second horizontal direction and that surrounds the plurality of nanosheets on the fin-type active region, and includes respective sub-gate portions between the plurality of nanosheets and a main gate portion above the uppermost layer of the plurality of nanosheets, a source/drain region disposed on the fin-type active region, adjacent to the gate line, and connected to the plurality of nanosheets, and a plurality of inner spacers interposed between the gate line and the source/drain region. The shapes of first inner spacers that face the sub-gate portions differ from the shape of a second inner spacer that faces the main gate portion.

### CROSS-REFERENCE TO RELATED APPLICATION

This application claims priority under 35 U.S.C. §119 from Korean Patent Application Nos. 10-2023-0039170, filed on Mar. 24, 2023, and 10-2023-0061261, filed on May 11, 2023 in the Korean Intellectual Property Office, the contents of both of which are herein incorporated by reference in their entireties.

### TECHNICAL FIELD

Embodiments of the inventive concept are directed to an integrated circuit device, and more particularly, to an integrated circuit device that includes a field-effect transistor.

### DISCUSSION

As integrated circuit devices are becoming more down-scaled, a fast operating speed and operation accuracy need to be ensured. In addition, as the degree of integration of an integrated circuit device increases and the size thereof decreases, the possibility a process failure increases in a process of manufacturing a nanosheet field-effect transistor. Accordingly, a novel-structured integrated circuit device that can prevent process failures and increase the performance and reliability of a nanosheet field-effect transistor is desired.

### SUMMARY

Embodiments of the inventive concept provide an integrated circuit device that provides stable performance and increased reliability in a nanosheet field-effect transistor.

According to an embodiment of the inventive concept, there is provided an integrated circuit device that includes a fin-type active region that protrudes from a substrate and extends in a first horizontal direction, a plurality of nanosheets disposed on the fin-type active region and separated from each other in the vertical direction, a gate line that extends in a second horizontal direction perpendicular to the first horizontal direction and surrounds the plurality of nanosheets on the fin-type active region, where the gate line includes respective sub-gate portions interposed between the plurality of nanosheets and a main gate portion disposed above the uppermost layer of the plurality of nanosheets, a source/drain region disposed on the fin-type active region, adjacent to the gate line, and connected to the plurality of nanosheets, and a plurality of inner spacers interposed between the gate line and the source/drain region. The shapes of first inner spacers that face the sub-gate portions differ from the shape of a second inner spacer that faces the main gate portion.

According to another embodiment of the inventive concept, there is provided an integrated circuit device that includes a fin-type active region that protrudes from a substrate and extends in a first horizontal direction, a plurality of nanosheets disposed on the fin-type active region and separated from each other in the vertical direction, a gate line that extends in a second horizontal direction perpendicular to the first horizontal direction and that surrounds the plurality of nanosheets on the fin-type active region, where the gate line includes respective sub-gate portion interposed between the plurality of nanosheets and a main gate portion disposed above the uppermost layer of the plurality of nanosheets, a source/drain region disposed on the fin-type active region, adjacent to the gate line, and connected to the plurality of nanosheets, a plurality of inner spacers interposed between the gate line and the source/drain region, and an outer spacer. . . . The main gate portion has an inverted T shape in which the horizontal width of a lower region is greater than the horizontal width of an upper region, no inner spacer is disposed on a sidewall of the lower region of the main gate portion, and the outer spacer is disposed on a sidewall of the upper region of the main gate portion.

According to another embodiment of the inventive concept, there is provided an integrated circuit device that includes a fin-type active region that protrudes from a substrate and extends in a first horizontal direction, a plurality of nanosheet layers disposed on the fin-type active region and separated from each other in the vertical direction, a gate line that extends in a second horizontal direction perpendicular to the first horizontal direction and that surrounds the plurality of nanosheet layers on the fin-type active region, where the gate line includes sub-gate portions interposed between the plurality of nanosheet layers and a main gate portion disposed above the uppermost layer of the plurality of nanosheet layers, a source/drain region disposed on the fin-type active region, adjacent to the gate line, and connected to the plurality of layers of nanosheets, an inter-gate insulating layer adjacent to the gate line on the source/drain region, a plurality of inner spacer layers including first inner spacers interposed between the sub-gate portions and the source/drain region and a second inner spacer interposed between a lower region of the main gate portion and the source/drain region, an outer spacer interposed between an upper region of the main gate portion and the inter-gate insulating layer, and a gate dielectric layer that surrounds the gate line. The shapes of the first inner spacers that face the sub-gate portions under the plurality of nanosheet layers differ from the shape of a second inner spacer that faces the lower region of the main gate portion.

### BRIEF DESCRIPTION OF THE DRAWINGS

FIG. 1 is a schematic layout of an integrated circuit device according to an embodiment.

FIG. 2 is a cross-sectional view taken along line A1-A1′ of FIG. 1.

FIG. 3 is a cross-sectional view taken along line A2-A2′ of FIG. 1.

FIG. 4 is a magnified view of portion CX1 of FIG. 2.

FIGS. 5 to 12 are cross-sectional views and magnified views of integrated circuit devices according to embodiments.

FIGS. 13 to 24 are cross-sectional views that illustrate a method of manufacturing an integrated circuit device according to an embodiment.

FIG. 25 is a block diagram of a system that includes an integrated circuit device, according to an embodiment.

### DETAILED DESCRIPTION

Hereinafter, embodiments are described in detail with reference to the accompanying drawings.

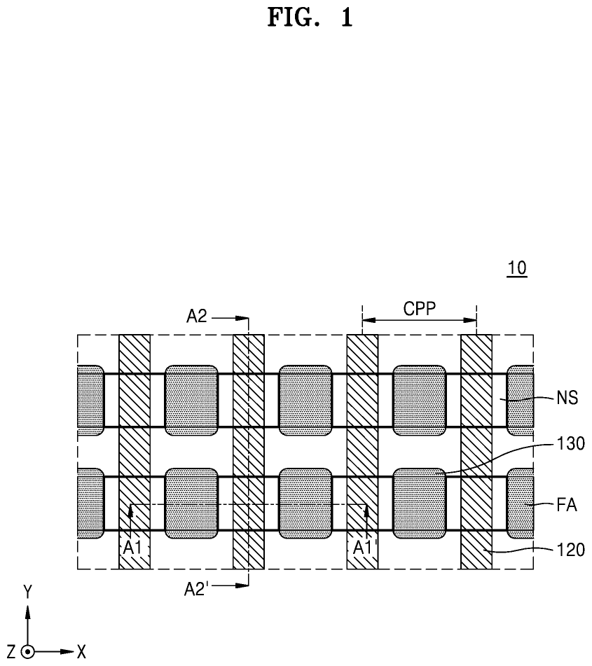

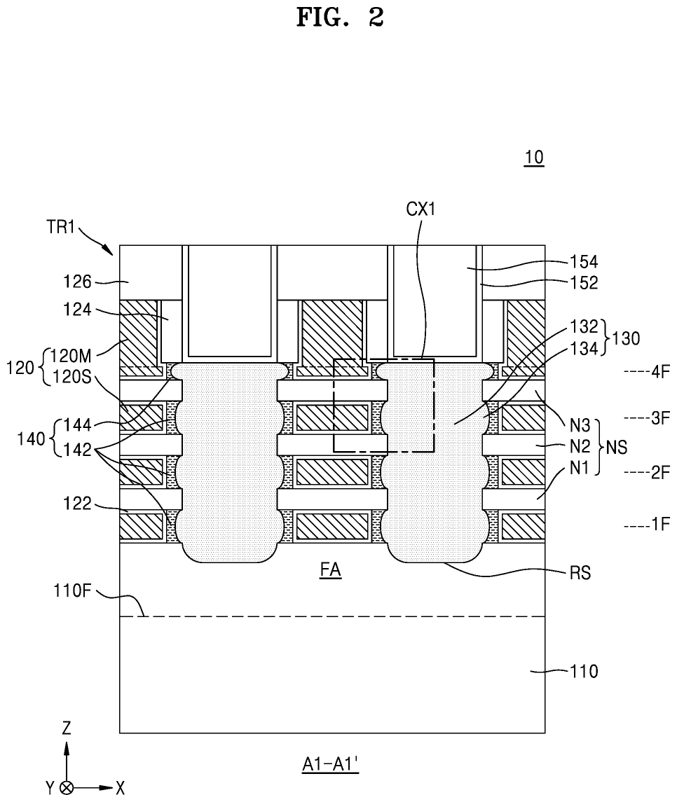

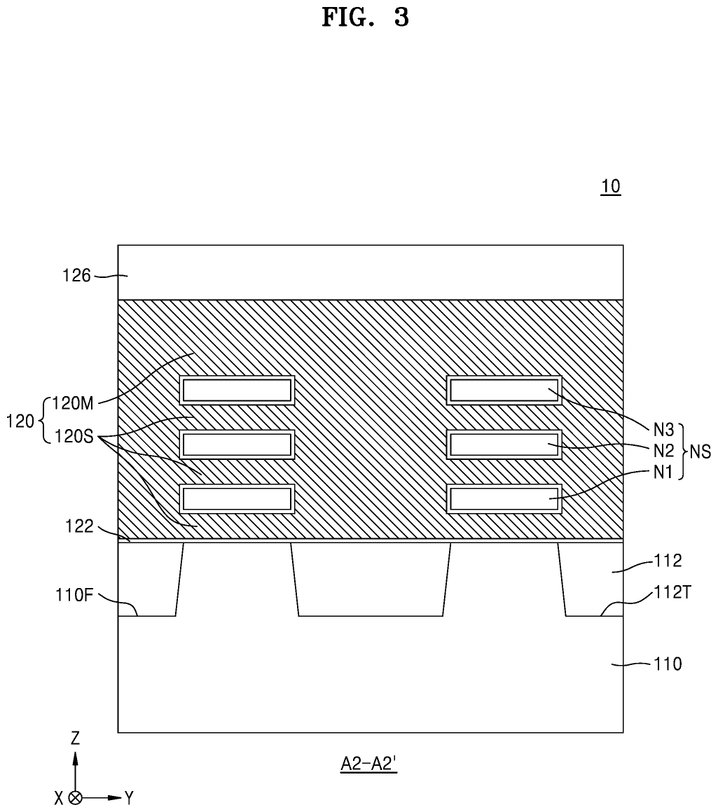

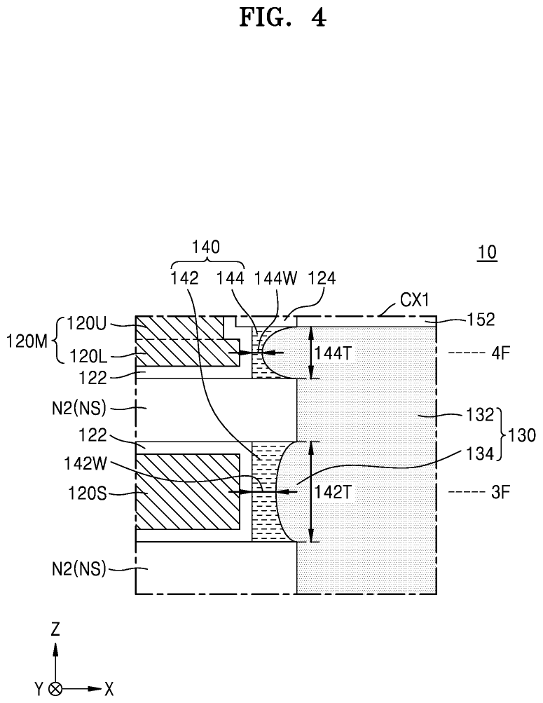

FIG. 1 is a schematic layout of an integrated circuit device 10 according to an embodiment, FIG. 2 is a cross-sectional view taken along line A1-A1′ of FIG. 1, FIG. 3 is a cross-sectional view taken along line A2-A2′ of FIG. 1, and FIG. 4 is a magnified view of portion CX1 of FIG. 2.

Referring to FIGS. 1 to 4, the integrated circuit device 10 according to an embodiment of the inventive concept includes a transistor TRI formed on a substrate 110, and the transistor TRI is a logic cell that includes a multi-bridge channel field-effect transistor (MBCFET).

In some embodiments, the transistor TRI is a p-type metal oxide semiconductor (pMOS) transistor or an n-type MOS (nMOS) transistor. In addition, the pMOS transistor and the nMOS transistor may have the same shape or different shapes. For example, an inner spacer to be described below can have various shapes that are the same as or different from each other in the pMOS transistor and the nMOS transistor.

The substrate 110 is a wafer that includes silicon (Si). In some embodiments, the substrate 110 is a wafer that includes a semiconductor element, such as germanium (Ge), or a compound semiconductor, such as one of silicon carbide (SiC), gallium arsenide (GaAs), indium arsenide (InAs), or indium phosphide (InP). In addition, the substrate 110 has a silicon on insulator (SOI) structure. On a first surface 110F of the substrate 110, a plurality of fin-type active regions FA protrude from the first surface 110F and extend in a first horizontal direction (X direction).

On the first surface 110F of the substrate 110, a device isolation layer 112 covers a lower side of a sidewall of a fin-type active region FA. The device isolation layer 112 fills a device isolation trench 112T that extends inward from the first surface 110F of the substrate 110 and has a double-layer structure of an interface layer and a buried insulating layer.

In some embodiments, a plurality of nanosheets NS are disposed above the fin-type active region FA, and the plurality of nanosheets NS are separated from each other in the vertical direction (Z direction). Each of the plurality of nanosheets NS includes a semiconductor element, such as Si or Ge, or a compound semiconductor, such as SiC, GaAs, InAs, or InP.

Each of the plurality of nanosheets NS is a semiconductor that has a relatively large width in a second horizontal direction (Y direction) and a relatively small thickness in the vertical direction (Z direction). For example, cach of the plurality of nanosheets NS has a width within a range of about 5 nm to about 100 nm in the second horizontal direction (Y direction) and a thickness within a range of about 1 nm to about 10 nm in the vertical direction (Z direction), but embodiments are not necessarily limited thereto. In some embodiments, at least one of the plurality of nanosheets NS has a different thickness in the vertical direction (Z direction) from the other nanosheets NS.

In some embodiments, the plurality of nanosheets NS include a first nanosheet N1, a second nanosheet N2, and a third nanosheet N3 disposed on the fin-type active region FA and that be separated from each other in the vertical direction (Z direction). However, the number of nanosheets NS is not necessarily limited thereto. Each of the plurality of nanosheets NS functions as a channel region.

A plurality of gate lines 120 extend in the second horizontal direction (Y direction) and surround the plurality of nanosheets NS, and are separated from each other in the first horizontal direction (X direction) by first gate intervals CPP.

In some embodiments, the plurality of gate lines 120 include at least one of doped polysilicon, a metal, a conductive metal nitride, a conductive metal carbide, a conductive metal silicide, or a combination thereof. For example, the plurality of gate lines 120 includes at least one of aluminum (Al), copper (Cu), titanium (Ti), tantalum (Ta), tungsten (W), molybdenum (Mo), tantalum nitride (TaN), nickel silicide (NiSi), cobalt silicide (CoSi), titanium nitride (TIN), tungsten nitride (WN), titanium aluminide (TiAl), titanium aluminum nitride (TiAIN), tantalum carbonitride (TaCN), tantalum carbide (TaC), tantalum silicon nitride (TaSiN), or a combination thereof, but are not necessarily limited thereto. In some embodiments, the plurality of gate lines 120 include a work function metal containing layer and a gap-fill metal layer. In some embodiments, the plurality of gate lines 120 include one of a stacked structure of titanium aluminum carbide (TiAIC)/TiN/W, a stacked structure of TiN/TaN/TiAIC/TiN/W, or a stacked structure of TiN/TaN/TiN/TiAIC/TiN/W, but embodiments are not necessarily limited thereto.

In some embodiments, each of the plurality of gate lines 120 includes a main gate portion 120M above the uppermost nanosheet NS and respective sub-gate portions 120S under the plurality of nanosheets NS. For example, the main gate portion 120M covers the upper surface of the third nanosheet N3, and the sub-gate portions 120S are interposed between the fin-type active region FA and the first nanosheet N1, between the first nanosheet NI and the second nanosheet N2, and between the second nanosheet N2 and the third nanosheet N3, respectively.

In the integrated circuit device 10 according to embodiments of the inventive concept, the main gate portion 120M include an upper region 120U and a lower region 120L that have different widths in a first horizontal direction (X direction). For example, the main gate portion 120M has an inverted T shape in which the horizontal width of the lower region 120L is greater than the horizontal width of the upper region 120U. In addition, the thickness of the lower region 120L of the main gate portion 120M in the vertical direction (Z direction) is less than the thickness of a sub-gate portion 120S in the vertical direction (Z direction). In addition, the horizontal width of the lower region 120L of the main gate portion 120M is substantially the same as the horizontal width of the sub-gate portion 120S.

In each of the plurality of gate lines 120, an outer spacer 124 faces a sidewall of the upper region 120U of the main gate portion 120M, and an inner spacer 140 faces a sidewall of the lower region 120L of the main gate portion 120M. The outer spacer 124 overlaps the inner spacer 140 in the vertical direction (Z direction). In addition, the outer spacer 124 and the inner spacer 140 are separated from a gate line 120 by a gate dielectric layer 122 therebetween. In some embodiments, the outer spacer 124 includes at least one of Si oxide, Si nitride, Si oxynitride, Si carbonitride, Si oxycarbonitride, or a combination thereof. The inner spacer 140 is described below in detail.

The gate dielectric layer 122 is interposed between the plurality of gate lines 120 and the plurality of nanosheets NS. For example, the gate dielectric layer 122 is interposed between the main gate portion 120M of each of the plurality of gate lines 120 and the uppermost nanosheet NS, between the sub-gate portions 120S and the plurality of nanosheets NS, and between the sub-gate portion 120S and the upper surface of the fin-type active region FA.

In some embodiments, the gate dielectric layer 122 includes at least one of Si oxide, Si oxynitride, a high-k material that has a higher dielectric constant than the Si oxide, or a combination thereof. The high-k material includes one of a metal oxide or a metal oxynitride. For example, the high-k material of the gate dielectric layer 122 includes at least one of hafnium oxide (HfO), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), zirconium oxide (ZrO), aluminum oxide (A1O), or a combination thereof, but is not necessarily limited thereto.

A plurality of recesses RS are formed that extends into the plurality of fin-type active regions FA at both sides of the plurality of gate lines 120, respectively, and a plurality of source/drain regions 130 are formed in the plurality of recesses RS, respectively. Each of the plurality of source/drain regions 130 is connected to opposite end portions of the plurality of nanosheets NS.

A source/drain region 130 includes a main source/drain portion 132 and protruding source/drain portions 134. In some embodiments, the main source/drain portion 132 is flat along the vertical direction (Z direction) on the inner wall of each of the plurality of recesses RS. In addition, the protruding source/drain portions 134 protrude from the inner wall of each of the plurality of recesses RS and are in direct contact with the plurality of inner spacers 140, respectively. For example, an outer wall of the source/drain region 130 has an embossed shape.

The integrated circuit device 10 according to an embodiment of the inventive concept includes the plurality of inner spacers 140 interposed between the sub-gate portions 120S of the gate line 120 and the source/drain region 130, and between the lower region 120L of the main gate portion 120M of the gate line 120 and the source/drain region 130. In some embodiments, the plurality of inner spacers 140 include at least one of Si oxide, Si nitride, Si oxynitride, Si carbonitride, Si oxycarbonitride, or a combination thereof.

Each of the plurality of inner spacers 140 has a first sidewall in direct contact with the source/drain region 130 and a second sidewall in direct contact with the gate dielectric layer 122. The first sidewall of each of the plurality of inner spacers 140 has a recessed curved surface shape, and the second sidewall thereof has a flat planar shape. For example, the first sidewall of each of the plurality of inner spacers 140 has a recessed shape that corresponds to and is in direct contact with a protruding source/drain portion 134 of the source/drain region 130.

For example, the plurality of inner spacers 140 include first inner spacers 142 respectively positioned beneath the plurality of nanosheets NS and respectively arranged between the source/drain region 130 and the sub-gate portions 120S that face the source/drain region 130, and a second inner spacer 144 disposed on the uppermost layer of the plurality of nanosheets NS and between the source/drain region 130 and the lower region 120L of the main gate portion 120M that faces the source/drain region 130.

In some embodiments, the shapes of the first inner spacers 142 differ from the shape of the second inner spacer 144. For example, a first thickness 142T of a first inner spacer 142 in the vertical direction (Z direction) is greater than a second thickness 144T of the second inner spacer 144 in the vertical direction (Z direction). In addition, a width 142W of a central portion of the first inner spacer 142 in the first horizontal direction (X direction) is greater than a width 144W of a central portion of the second inner spacer 144 in the first horizontal direction (X direction). Accordingly, the first sidewall of the first inner spacer 142 has a greater radius of curvature than a first sidewall of the second inner spacer 144.

In some embodiments, a second sidewall of at least one of the first inner spacers 142 and the second inner spacer 144 has a shape recessed into the plurality of inner spacers 140 instead of being flat as shown in FIG. 2. Correspondingly, a sidewall of at least one of the lower region 120L of the main gate portion 120M, the sub-gate portions 120S, or the gate dielectric layer 122 in contact with the sidewall also has a shape that protrudes in the first horizontal direction (X direction) into the plurality of inner spacers 140.

In some embodiments, the first inner spacers 142 are respectively disposed in a first layer IF, a second layer 2F, and a third layer 3F, and the second inner spacer 144 is disposed only in a fourth layer 4F. For example, the first inner spacers 142 include three layers, but are not necessarily limited thereto. In the specification, layers refer to vertical levels spaced apart from the substrate 110 at predetermined intervals in the vertical direction (Z direction).

For example, the first inner spacer 142 in the first layer IF is located beneath the first nanosheet N1, the first inner spacer 142 in the second layer 2F is located beneath the second nanosheet N2, the first inner spacer 142 in the third layer 3F is located beneath the third nanosheet N3, and the second inner spacer 144 in the fourth layer 4F is positioned on the third nanosheet N3. For example, the lower surface of the second inner spacer 144 in the fourth layer 4F is in direct contact with the upper surface of the third nanosheet N3, and the upper surface thereof is in direct contact with the lower surface of the outer spacer 124.

A gate capping layer 126 is disposed on the plurality of gate lines 120 and the outer spacer 124, and a passivation layer 152 and an inter-gate insulating layer 154 are formed that cover a source/drain region 130 between two adjacent gate lines 120. In some embodiments, the passivation layer 152 and the inter-gate insulating layer 154 include at least one of Si oxide, Si nitride, Si oxynitride, Si carbonitride, Si oxycarbonitride, or a combination thereof.

In addition, a back-end-of-line (BEOL) structure may be disposed on the gate capping layer 126 and the inter-gate insulating layer 154. The BEOL structure includes a contact that is electrically connected to the source/drain region 130 and/or a gate line 120, a via connected to the contact, and a metal wiring connected to the via.

In addition, a backside power delivery network may be further formed on the lower surface of the substrate 110, and a connection structure, such as a via contact, is formed that connects the backside power delivery network to the upper surface of the source/drain region 130 or the lower surface of the source/drain region 130 .

In an MBCFET that includes the plurality of nanosheets NS, a process of forming the gate line 120 that surrounds the plurality of nanosheets NS is challenging. For example, in a process of replacing a sacrificial pattern located between the plurality of nanosheets NS with the gate line 120, an electrical short circuit between the source/drain region 130 and the gate line 120 can easily occur. To prevent the electrical short circuit, a method of forming the plurality of inner spacers 140 between the gate line 120 and the source/drain region 130 is proposed.

According to embodiments of the technical idea of the inventive concept, the second inner spacer 144 is also formed on the sidewall of the lower region 120L of the main gate portion 120M. For example, because the thickness of the lower region 120L of the main gate portion 120M is less than the thickness of the sub-gate portion 120S, the shape of the second inner spacer 144 formed in the uppermost layer differs from the shapes of the first inner spacers 142 formed in the other layers.

Eventually, in the integrated circuit device 10 according to embodiments of the technical idea of the inventive concept, the shapes of the first inner spacers 142 that respectively face the sub-gate portions 120S are differently implemented from the shape of the second inner spacer 144 that faces the lower region 120L of the main gate portion 120M, thereby providing stable performance and increased reliability in a nanosheet FET.

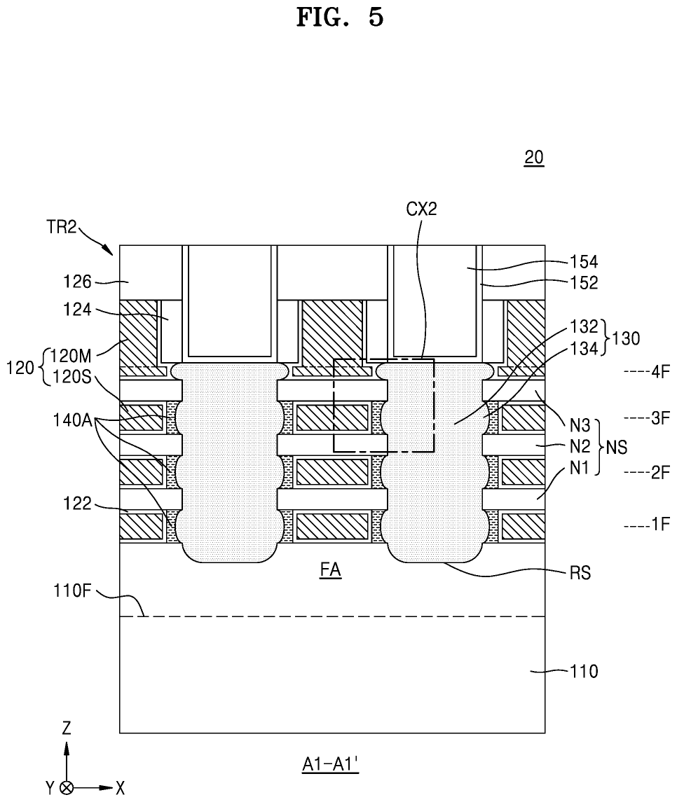

FIGS. 5 to 12 are cross-sectional views and magnified views of integrated circuit devices 20, 30, 40, and 50 according to other embodiments.

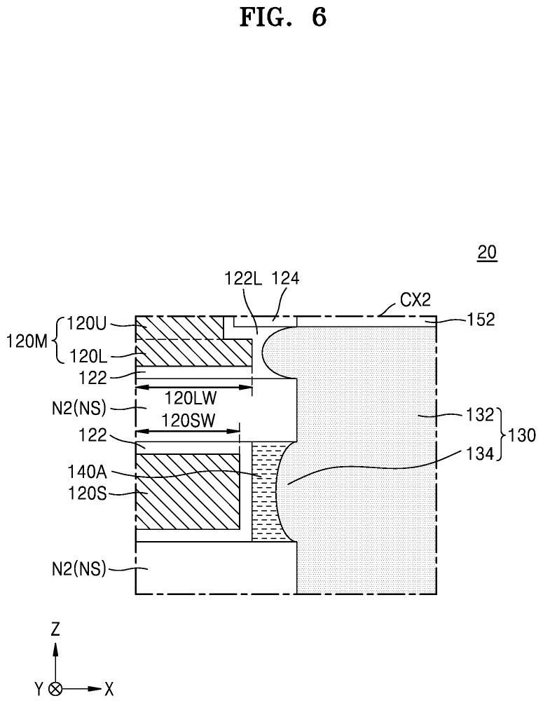

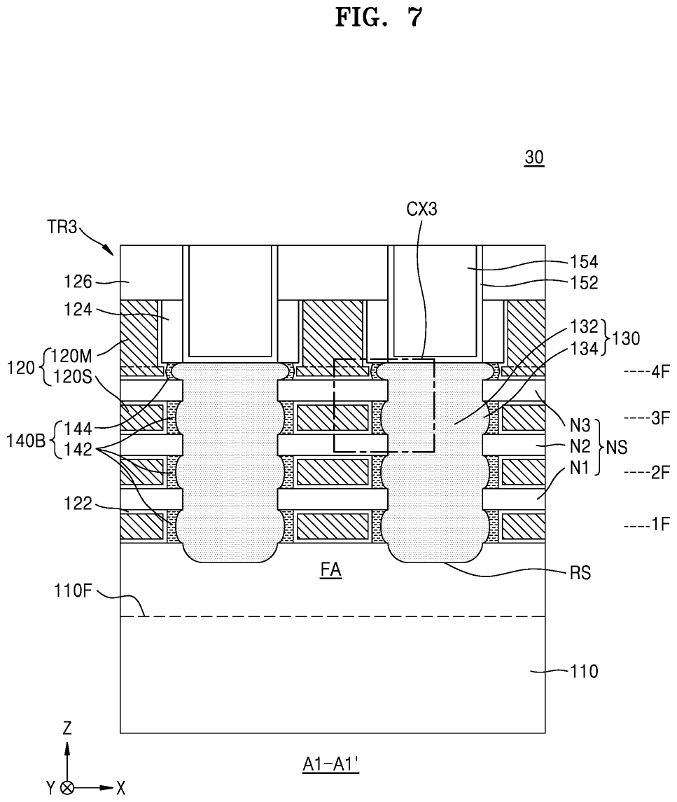

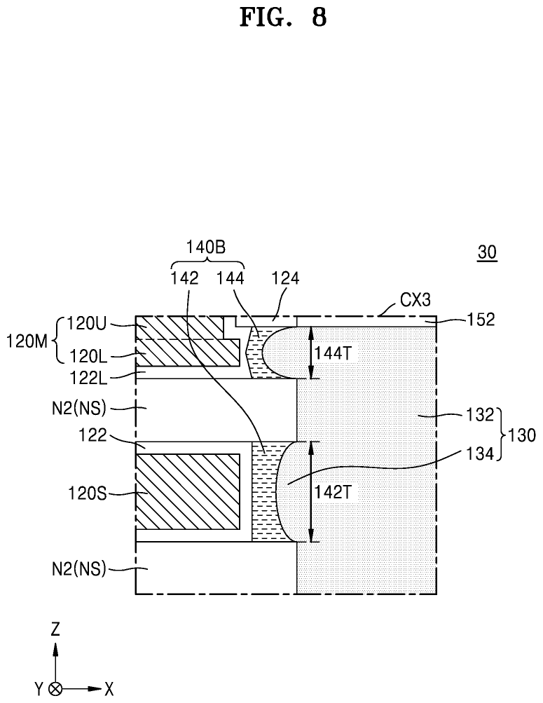

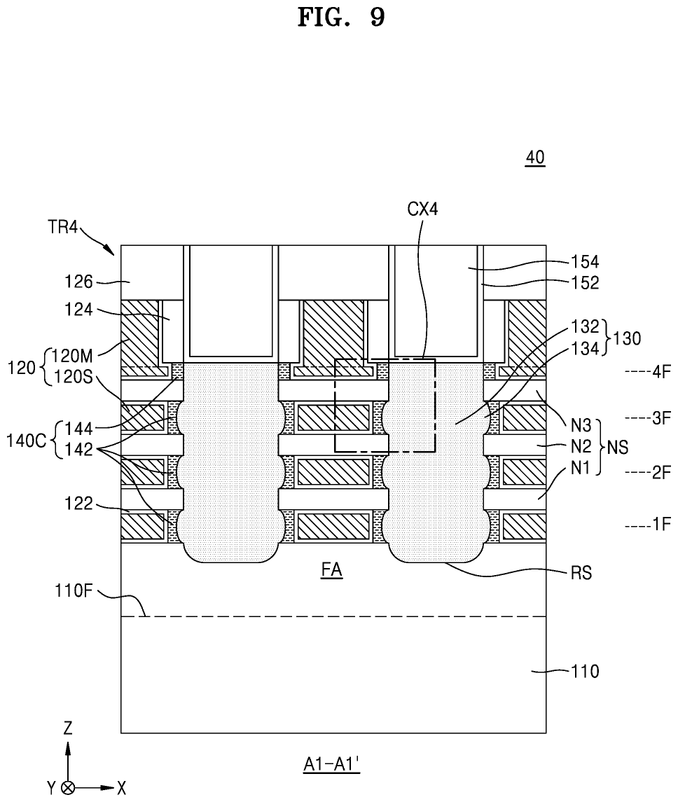

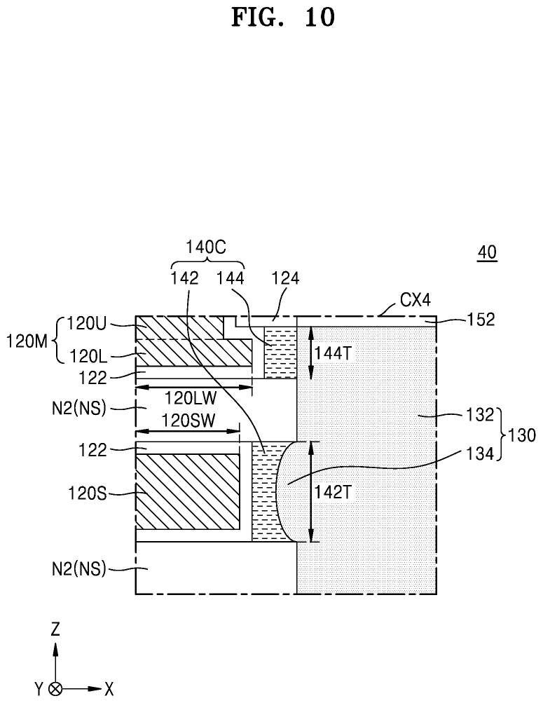

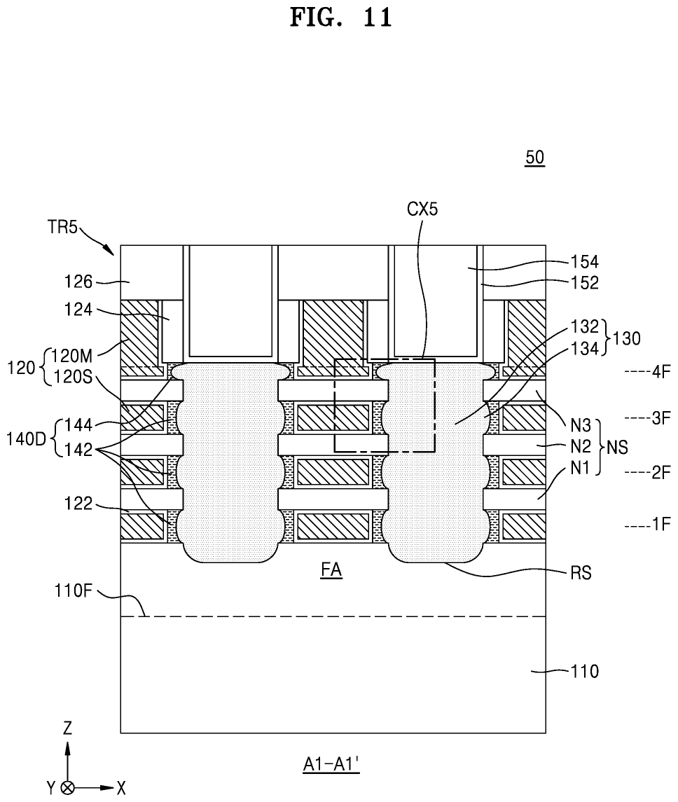

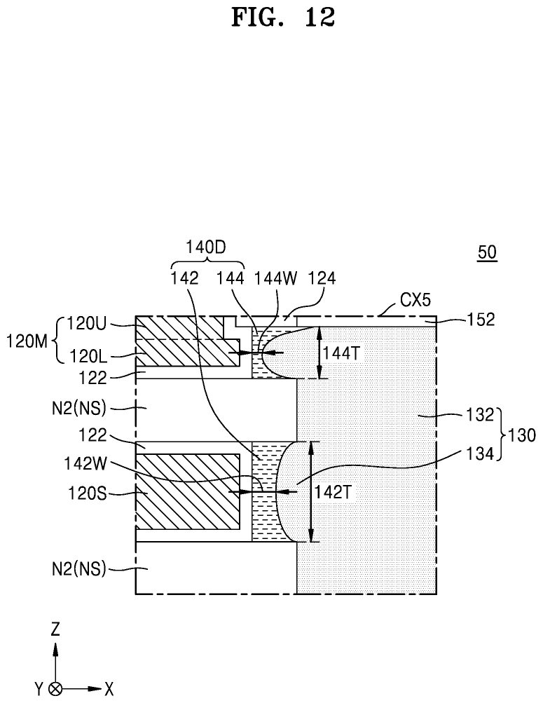

For example, FIGS. 5, 7, 9, and 11 are cross-sectional views taken along the line Al-Al' of FIG. 1, FIG. 6 is a magnified view of portion CX2 of FIG. 5, FIG. 8 is a magnified view of portion CX3 of FIG. 7, FIG. 10 is a magnified view of portion CX4 of FIG. 9, and FIG. 12 is a magnified view of portion CX5 of FIG. 11.

Most components of the integrated circuit devices 20, 30, 40, and 50 to be described below and materials forming the components are substantially the same as or similar to those described above with reference to FIGS. 1 to 4. Therefore, for convenience of description, differences from the integrated circuit device 10 described above are mainly described.

Referring to FIGS. 5 and 6, the integrated circuit device 20 according to an embodiment of the inventive concept includes a transistor TR2 formed on the substrate 110, and the transistor TR2 is a logic cell that includes an MBCFET.

The main gate portion 120M of the integrated circuit device 20 according to an embodiment of the inventive concept includes the upper region 120U and the lower region 120L with different widths in the first horizontal direction (X direction). For example, the main gate portion 120M has an inverted T shape in which the horizontal width of the lower region 120L is greater than the horizontal width of the upper region 120U. The thickness of the lower region 120L of the main gate portion 120M in the vertical direction (Z direction) is less than the thickness of the sub-gate portion 120S in the vertical direction (Z direction). In addition, a horizontal width 120LW of the lower region 120L of the main gate portion 120M is greater than a horizontal width 120SW of the sub-gate portion 120S.

The integrated circuit device 20 according to an embodiment of the inventive concept includes inner spacers 140A that are interposed between the sub-gate portions 120S of the gate line 120 and the source/drain region 130, but not between the lower region 120L of the main gate portion 120M of the gate line 120 and the source/drain region 130.

An inner spacer 140A has a first sidewall in direct contact with the source/drain region 130 and a second sidewall in direct contact with the gate dielectric layer 122. The first sidewall of the inner spacer 140A has a recessed curved surface shape, and the second sidewall thereof has a flat planar surface. For example, the first sidewall of the inner spacer 140A has a recessed shape that corresponds to and is in direct contact with a protruding source/drain portion 134 of the source/drain region 130.

An outer wall of a gate dielectric layer 122L of the integrated circuit device 20 according to an embodiment of the inventive concept, surrounds the lower region 120L of the main gate portion 120M and has a recessed curved surface. For example, because no inner spacer is interposed between the lower region 120L of the main gate portion 120M and the source/drain region 130, the outer wall of the gate dielectric layer 122L has a recessed shape that corresponds to and is in direct contact with a protruding source/drain portion 134 of the source/drain region 130.

Referring to FIGS. 7 and 8, the integrated circuit device 30 according to an embodiment of the inventive concept includes a transistor TR3 formed on the substrate 110, and the transistor TR3 is a logic cell that includes an MBCFET.

The integrated circuit device 30 according to an embodiment of the inventive concept includes a plurality of inner spacers 140B that are interposed between the sub-gate portions 120S of the gate line 120 and the source/drain region 130, and between the lower region 120L of the main gate portion 120M of the gate line 120 and the source/drain region 130.

Each of the plurality of inner spacers 140B has a first sidewall in direct contact with the source/drain region 130 and a second sidewall in direct contact with the gate dielectric layer 122. The first sidewall of each of the plurality of inner spacers 140B has a recessed curved surface, and the second sidewall thereof has a flat planar surface or a surface with a sharp central portion.

For example, the plurality of inner spacers 140B includes the first inner spacers 142 that are interposed between the plurality of nanosheets NS and between the source/drain region 130 and the sub-gate portions 120S that faces the source/drain region 130, and the second inner spacer 144 disposed on the uppermost layer of the plurality of nanosheets NS and between the source/drain region 130 and the lower region 120L of the main gate portion 120M that faces the source/drain region 130.

In some embodiments, the shapes of the first inner spacers 142 differ from the shape of the second inner spacer 144. For example, the first thickness 142T of a first inner spacer 142 in the vertical direction (Z direction) is greater than the second thickness 144T of the second inner spacer 144 in the vertical direction (Z direction). In addition, the second sidewall of the first inner spacer 142 has a flat planar surface, but the second sidewall of the second inner spacer 144 has a surface with a sharp central portion.

The gate dielectric layer 122L of the integrated circuit device 30 according to an embodiment of the inventive concept that surrounds the lower region 120L of the main gate portion 120M has an outer wall with a pitted central portion. For example, between the lower region 120L of the main gate portion 120M and the source/drain region 130, the outer wall of the gate dielectric layer 122L has a recessed shape that corresponds to and is in direct contact with the second sidewall of the second inner spacer 144. For example, the outer wall of the gate dielectric layer 122L and the second sidewall of the second inner spacer 144 each include two flat planar surfaces that are inclined with respect to a vertical direction (Z direction) and meet at line that extends in the second horizontal direction (Y direction).

Referring to FIGS. 9 and 10, the integrated circuit device 40 according to an embodiment of the inventive concept includes a transistor TR4 formed on the substrate 110, and the transistor TR4 is a logic cell that includes an MBCFET.

The main gate portion 120M of the integrated circuit device 40 according to an embodiment of the inventive concept, the includes the upper region 120U and the lower region 120L that have different widths in the first horizontal direction (X direction). For example, the main gate portion 120M has an inverted T shape, and the horizontal width of the lower region 120L is greater than the horizontal width of the upper region 120U. The thickness of the lower region 120L of the main gate portion 120M in the vertical direction (Z direction) is less than the thickness of a sub-gate portion 120S in the vertical direction (Z direction). In addition, the horizontal width 120LW of the lower region 120L of the main gate portion 120M is greater than the horizontal width 120SW of the sub-gate portion 120S.

The integrated circuit device 40 according to an embodiment of the inventive concept includes a plurality of inner spacers 140C interposed between the sub-gate portions 120S of the gate line 120 and the source/drain region 130, and between the lower region 120L of the main gate portion 120M of the gate line 120 and the source/drain region 130.

Each of the plurality of inner spacers 140C has a first sidewall in direct contact with the source/drain region 130 and a second sidewall in direct contact with the gate dielectric layer 122. The first sidewall of each of the plurality of inner spacers 140C has a recessed curved surface or a flat planar surface, and the second sidewall thereof has a flat planar surface.

For example, the plurality of inner spacers 140C includes the first inner spacers 142 positioned between the plurality of nanosheets NS and arranged between the source/drain region 130 and the sub-gate portions 120S that face the source/drain region 130, and the second inner spacer 144 disposed on the uppermost layer of the plurality of nanosheets NS and between the source/drain region 130 and the lower region 120L of the main gate portion 120M that faces the source/drain region 130.

In some embodiments, the shapes of the first inner spacers 142 differ from the shape of the second inner spacer 144. For example, the first thickness 142T of a first inner spacer 142 in the vertical direction (Z direction) is greater than the second thickness 144T of the second inner spacer 144 in the vertical direction (Z direction). In addition, the first sidewall of the first inner spacer 142 has a recessed curved surface, but the first sidewall of the second inner spacer 144 has a flat planar surface.

Referring to FIGS. 11 and 12, the integrated circuit device 50 according to an embodiment of the inventive concept includes a transistor TR5 formed on the substrate 110, and the transistor TR5 is a logic cell that includes an MBCFET.

The integrated circuit device 50 according to an embodiment of the inventive concept includes a plurality of inner spacers 140D interposed between the sub-gate portions 120S of the gate line 120 and the source/drain region 130, and between the lower region 120L of the main gate portion 120M of the gate line 120 and the source/drain region 130.

Each of the plurality of inner spacers 140D has a first sidewall in direct contact with the source/drain region 130 and a second sidewall in direct contact with the gate dielectric layer 122. The first sidewall of each of the plurality of inner spacers 140D has a recessed curved surface, and the second sidewall thereof has a flat planar surface. For example, the first sidewall of each of the plurality of inner spacers 140D has a recessed surface that corresponds to and is in contact with a protruding source/drain portion 134 of the source/drain region 130.

For example, the plurality of inner spacers 140D include the first inner spacers 142 positioned between the plurality of nanosheets NS and arranged between the source/drain region 130 and the sub-gate portions 120S that face the source/drain region 130, and the second inner spacer 144 disposed on the uppermost layer of the plurality of nanosheets NS and between the source/drain region 130 and the lower region 120L of the main gate portion 120M that faces the source/drain region 130.

In some embodiments, the shapes of the first inner spacers 142 differ from the shape of the second inner spacer 144. For example, the first thickness 142T of a first inner spacer 142 in the vertical direction (Z direction) is greater than the second thickness 144T of the second inner spacer 144 in the vertical direction (Z direction). In addition, the width 142W of a central portion of the first inner spacer 142 in the first horizontal direction (X direction) is greater than the width 144W of a central portion of the second inner spacer 144 in the first horizontal direction (X direction).

In addition, the widths of the top and the bottom of the first inner spacer 142 in the first horizontal direction (X direction) are substantially the same as each other, while the widths of the top and the bottom of the second inner spacer 144 in the first horizontal direction (X direction) differ from each other. For example, the horizontal width of the top of the second inner spacer 144 is greater than the horizontal width of the bottom of the second inner spacer 144, and the top of the second inner spacer 144 extends into the main source/drain portion 132. In some embodiments, the top of the second inner spacer 144 protrudes further in the first horizontal direction (X direction) than a side surface of the outer spacer 124.

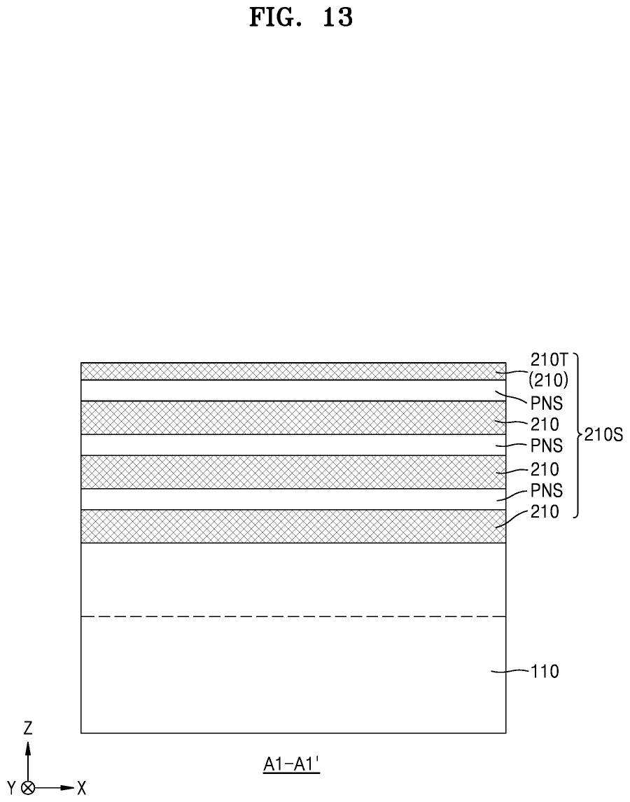

FIGS. 13 to 24 are cross-sectional views that illustrate a method of manufacturing an integrated circuit device, according to an embodiment.

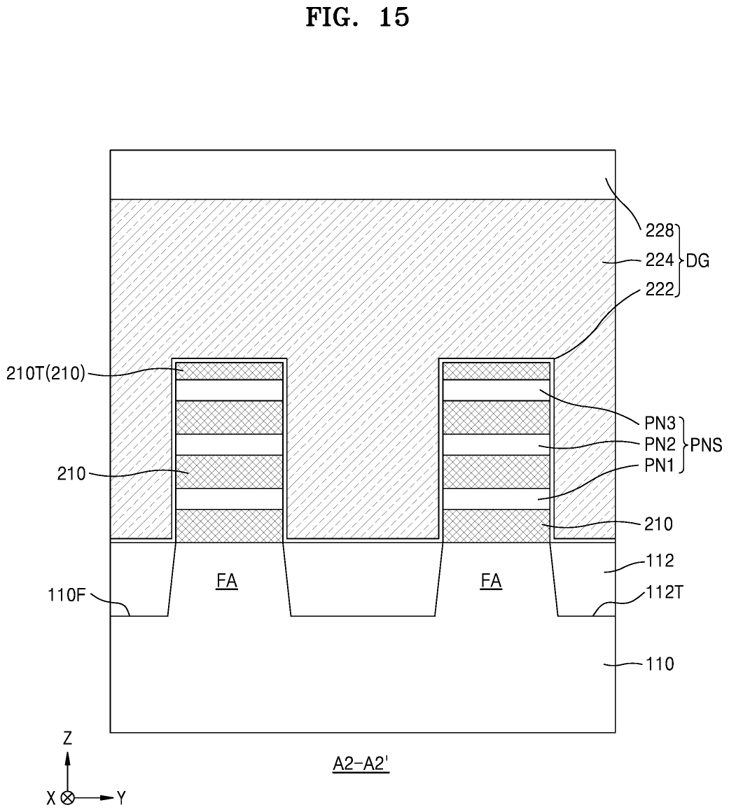

For example, FIGS. 13, 14, 16 to 19, and 21 to 23 are cross-sectional views taken along the line A1-A1′ of FIG. 1, and FIGS. 15, 20, and 24 are cross-sectional views taken along the line A2-A2′ of FIG. 1.

Referring to FIG. 13, in an embodiment, sacrificial layers 210 and nanosheet layers PNS are alternately formed on the upper surface of the substrate 110.

A stacked structure of the sacrificial layers 210 and the nanosheet layers PNS may be referred to as a nanosheet stack 210S.

In some embodiments, the sacrificial layers 210 and the nanosheet layers PNS are formed by an epitaxy process. In addition, the sacrificial layers 210 and the nanosheet layers PNS are formed of materials that have an etching selectivity with respect to each other. For example, each of the sacrificial layers 210 and the nanosheet layers PNS includes a monocrystalline layer of at least one of a group IV semiconductor, a group IV-IV compound semiconductor, or a group III-V compound semiconductor, where the material of the sacrificial layers 210 differs from the material of the nanosheet layers PNS. For example, the sacrificial layers 210 include silicon germanium (SiGe) and the nanosheet layers PNS include monocrystalline Si.

In some embodiments, the epitaxy process includes one of a vapor-phase epitaxy, a chemical vapor deposition (CVD) process such as ultra-high vacuum CVD (UHV-CVD), a molecular beam epitaxy, or a combination thereof. In the epitaxy process, a liquid or gaseous precursor may be used to form the sacrificial layers 210 and the nanosheet layers PNS.

At least one of the plurality of sacrificial layers 210 has a thickness in the vertical direction (Z direction) that differs from those of the other sacrificial layers 210. For example, the uppermost sacrificial layer 210T has a thickness in the vertical direction (Z direction) that is less than that of each of the other sacrificial layers 210.

The uppermost layer of the nanosheet stack 210S is formed of a sacrificial layer 210, not a nanosheet layer PNS. In some embodiments, a protective layer that covers the uppermost sacrificial layer 210T is further formed.

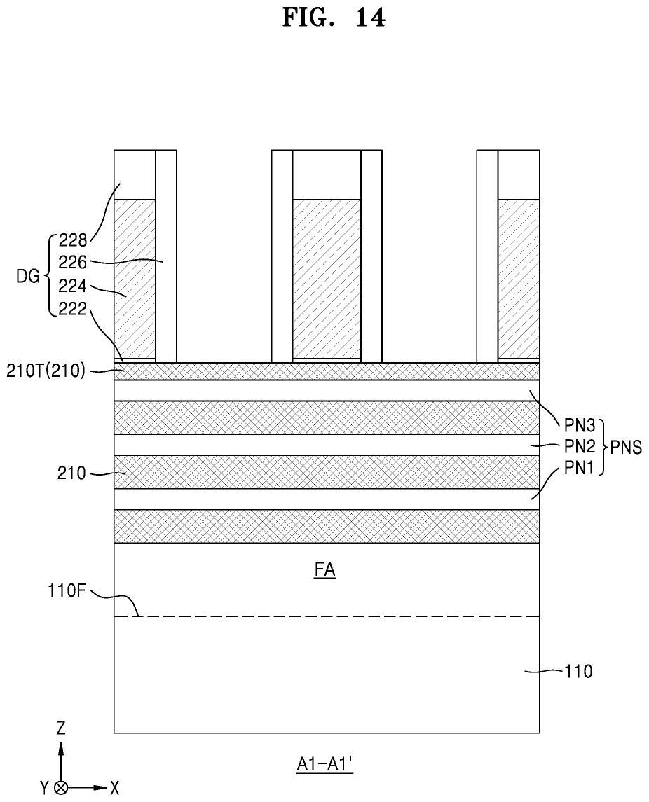

Referring to FIGS. 14 and 15, in an embodiment, a hard mask pattern is formed on the uppermost sacrificial layer 210T, and the hard mask pattern is used as an etching mask to etch the sacrificial layers 210, the nanosheet layers PNS, and the substrate 110.

The stacked structure of the nanosheet layers PNS and the sacrificial layers 210 has a line-type pattern shape that extends in the first horizontal direction (X direction), and the device isolation trench 112T is formed in the substrate 110 between stacked line patterns of the nanosheet layers PNS and the sacrificial layers 210.

For example, the nanosheet layers PNS include, on the first surface 110F of the substrate 110, a first nanosheet layer PN1, a second nanosheet layer PN2, and a third nanosheet layer PN3 separated from each other in the vertical direction (Z direction) by the sacrificial layers 210. The sacrificial layers 210 are formed between the upper surface of the substrate 110 and the first nanosheet layer PN1, between the first nanosheet layer PNI and the second nanosheet layer PN2, between the second nanosheet layer PN2 and the third nanosheet layer PN3, and on the upper surface of the third nanosheet layer PN3, respectively.

The device isolation trench 112T is filled with an insulating material, and then the top of the insulating material is planarized to form the device isolation layer 112 that fills the device isolation trench 112T. The fin-type active region FA in the substrate 110 is defined by the device isolation layer 112.

A sacrificial gate structure DG is formed on the device isolation layer 112 and the stacked line patterns of the nanoshect layers PNS and the sacrificial layers 210. The sacrificial gate structure DG includes a sacrificial insulating layer pattern 222, a sacrificial gate line 224, a sacrificial gate spacer 226, and a sacrificial gate capping layer 228.

The sacrificial insulating layer pattern 222 extends in the second horizontal direction (Y direction) and is conformally formed on the upper surfaces and sidewalls of the stacked line patterns of the nanosheet layers PNS and the sacrificial layers 210 and the upper surface of the device isolation layer 112. In some embodiments, the sacrificial insulating layer pattern 222 is formed of a material that has an etching selectivity with respect to the sacrificial gate line 224, such as formed of at least one of Si oxide, Si oxynitride, or Si nitride.

The sacrificial gate line 224 is formed to have a large vertical thickness to cover the stacked line patterns of the nanosheet layers PNS and the sacrificial layers 210 on the sacrificial insulating layer pattern 222. The upper surface of the sacrificial gate line 224 is flat. In some embodiments, the sacrificial gate line 224 is formed of polysilicon, but is not necessarily limited thereto.

The sacrificial gate spacer 226 is disposed on a sidewall of the sacrificial gate line 224 and includes, for example, at least one of Si oxide, Si nitride, Si oxynitride, Si carbonitride, Si oxycarbonitride, or a combination thereof.

The sacrificial gate capping layer 228 is disposed on the upper surface of the sacrificial gate line 224, and both sidewalls of the sacrificial gate capping layer 228 are covered by the sacrificial gate spacer 226. In some embodiments, the sacrificial gate capping layer 228 is formed of Si nitride.

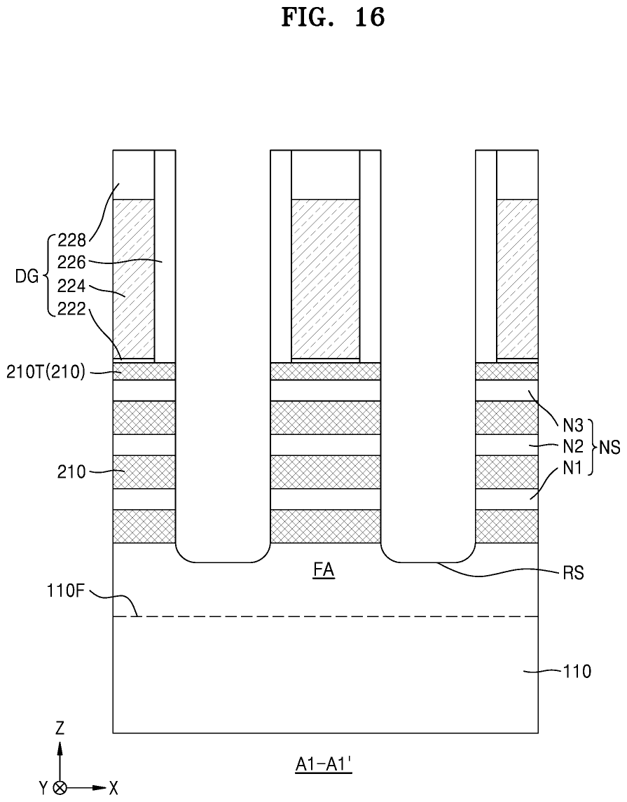

Referring to FIG. 16, in an embodiment, portions of the nanosheet layers PNS (see FIG. 14) and the sacrificial layers 210 at both sides of the sacrificial gate structure DG and a portion of the substrate 110 are etched to form recesses RS at both the sides of the sacrificial gate structure DG.

By forming the recesses RS, the nanosheet layers PNS are divided into the plurality of nanosheets NS. For example, by forming the recesses RS, a structure in which the plurality of sacrificial layers 210 and the plurality of nanosheets NS are alternately disposed is formed on the fin-type active region FA.

In some embodiments, as shown in FIG. 16, a recess RS includes sidewalls that continuously extend and are aligned with both sidewalls of the sacrificial gate structure DG, c.g., both sidewalls of the sacrificial gate spacer 226. For example, a sidewall of each of the plurality of nanosheets NS exposed by the recess RS is aligned with a sidewall of the sacrificial gate spacer 226 to form a flat sidewall profile.

In some embodiments, each of the recesses RS has a width that is constant along the height thereof, and accordingly, the plurality of nanosheets NS have substantially the same width in the first horizontal direction (X direction). In some embodiments, the recesses RS are formed with a lower width that is less than an upper width, and have a tapered sidewall profile, and accordingly, at least one of the plurality of nanosheets NS has a greater width than the other nanosheets NS.

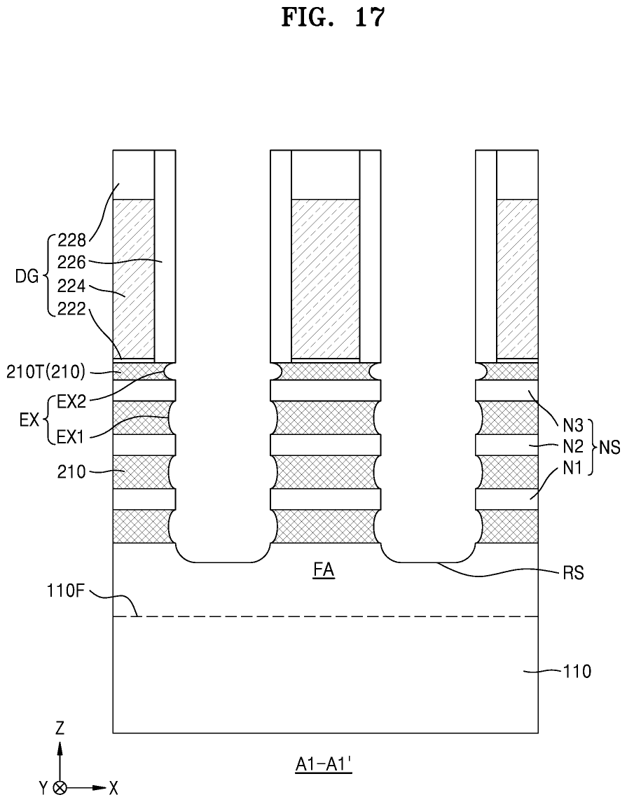

Referring to FIG. 17, in an embodiment, a plurality of indents EX are formed by removing portions of the plurality of sacrificial layers 210 exposed on the sidewall of the recess RS.

For example, a portion of a sacrificial layer 210 is removed by an etching process that has a selective etching characteristic for the sacrificial layer 210. In some embodiments, the plurality of indents EX are sidewall portions of the plurality of sacrificial layers 210 that are recessed inward from sidewalls of the plurality of nanosheets NS, or a space formed by a sidewall portion of the sacrificial layer 210 tht is recessed inward between every two adjacent nanosheets NS.

Because the uppermost sacrificial layer 210T is thinner in the vertical direction (Z direction) than the other sacrificial layers 210, a second indent EX2 formed in the uppermost sacrificial layer 210T is formed deeper than first indents EXI formed in the other sacrificial layers 210. For example, a first indent EXI has a greater radius of curvature than the second indent EX2.

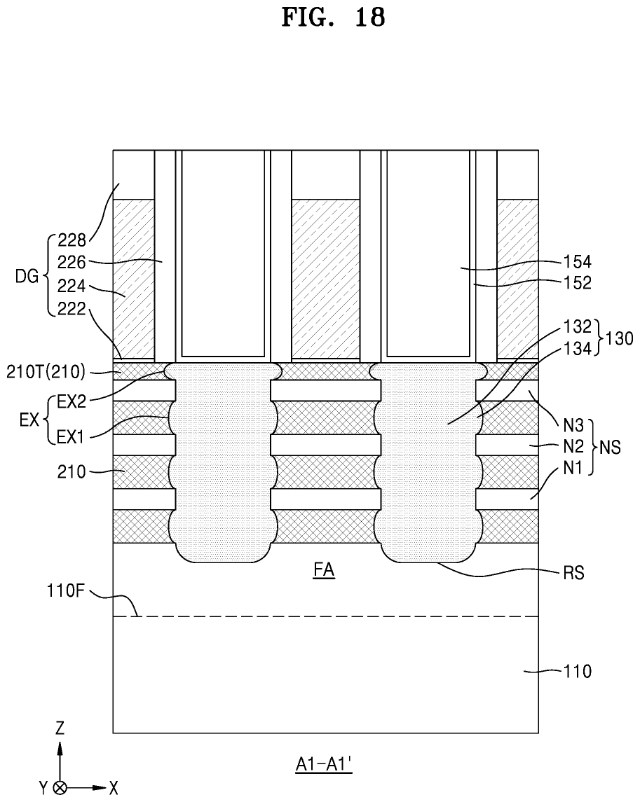

Referring to FIG. 18, in an embodiment, the plurality of source/drain regions 130 are formed in the plurality of recesses RS.

In some embodiments, a source/drain region 130 is formed by growing, by an cpitaxy process, a semiconductor material from the plurality of nanosheets NS, the plurality of sacrificial layers 210, and the surface of the substrate 110 that are exposed on the inner wall of a recess RS.

The source/drain region 130 is grown by an epitaxy process by using, as a seed layer, exposed sidewalls of the plurality of nanosheets NS on the inner wall of the recess RS, exposed surfaces of the plurality of indents EX that are sidewalls of the plurality of sacrificial layers 210, and the upper surface of the substrate 110 exposed on the bottom of the recess RS.

The source/drain region 130 are formed to fill in the recess RS. The upper surface of the source/drain region 130 is formed at substantially at the same vertical level as the upper surface of the uppermost sacrificial layer 210T.

The source/drain region 130 includes the main source/drain portion 132 and the protruding source/drain portions 134. In some embodiments, the main source/drain portion 132 has flat sidewall surfaces in the vertical direction (Z direction) in contact with inner walls of each of the plurality of recesses RS. In addition, the protruding source/drain portions 134 protrude into the plurality of indents EX.

The passivation layer 152 and the inter-gate insulating layer 154 are formed that cover the sacrificial gate structure DG and the source/drain region 130. The passivation layer 152 is formed to be thin, and the inter-gate insulating layer 154 is formed to fill in a space between two adjacent sacrificial gate structures DG. The upper surface of the inter-gate insulating layer 154 is formed at the same vertical level as the upper surface of the sacrificial gate structure DG.

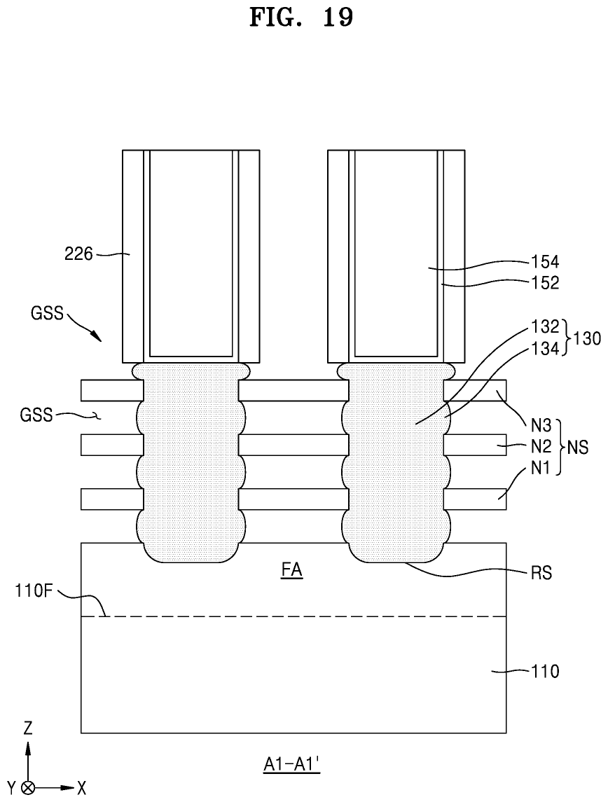

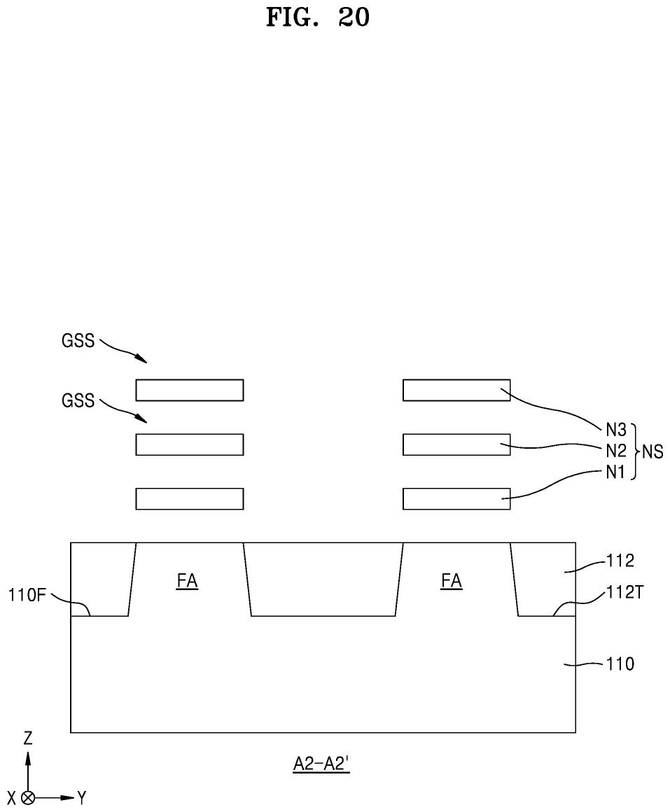

Referring to FIGS. 19 and 20, in an embodiment, the sacrificial gate capping layer 228 is removed by planarizing the top of the sacrificial gate structure DG and the top of the inter-gate insulating layer 154, and the upper surface of the sacrificial gate line 224 is exposed by the planarization process.

The sacrificial gate line 224 and the sacrificial insulating layer pattern 222 are removed to form a gate space GSS. For example, the gate space GSS is formed between two adjacent sacrificial gate spacers 226, and in the gate space GSS, sidewalls of the plurality of nanosheets NS and the upper surface of the uppermost sacrificial layer 210T (see FIG. 18) may be exposed.

The plurality of sacrificial layers 210 (see FIG. 18) that remain on the fin-type active region FA are fully removed through the gate space GSS to expose the upper surface of the fin-type active region FA, the upper surfaces and the lower surfaces of the plurality of nanosheets NS, and the sidewalls of the source/drain region 130. A process of removing the plurality of sacrificial layers 210 is a wet etching process that uses etching selectivity between the plurality of sacrificial layers 210 and the plurality of nanosheets NS.

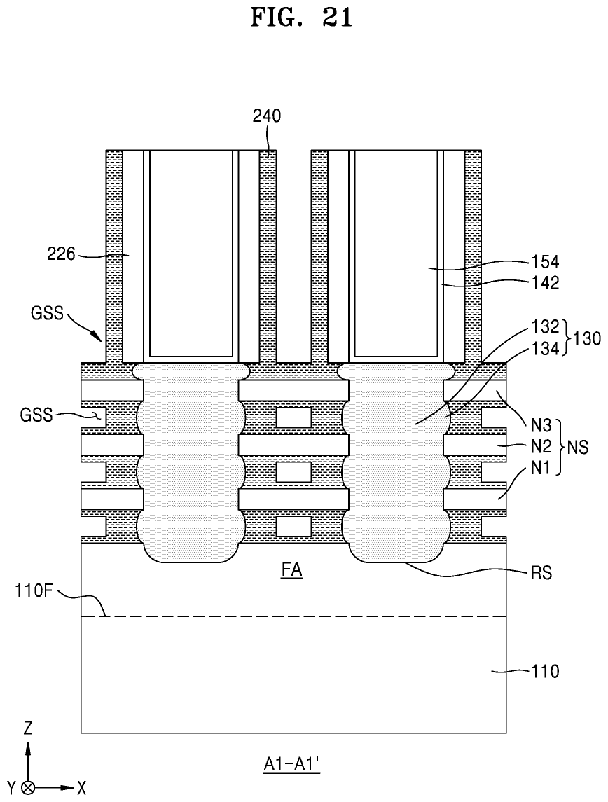

Referring to FIG. 21, in an embodiment, a spacer forming layer 240 that conformally surrounds the gate space GSS is formed.

The spacer forming layer 240 is formed between two adjacent sacrificial gate spacers 226, between two adjacent source/drain regions 130, and in direct contact with the upper surfaces and the lower surfaces of the plurality of nanosheets NS.

In some embodiments, a process of forming the spacer forming layer 240 is one of an oxidation process or a nitrification process. For example, the spacer forming layer 240 includes at least one of Si oxide, Si nitride, Si oxynitride, Si carbonitride, Si oxycarbonitride, or a combination thereof.

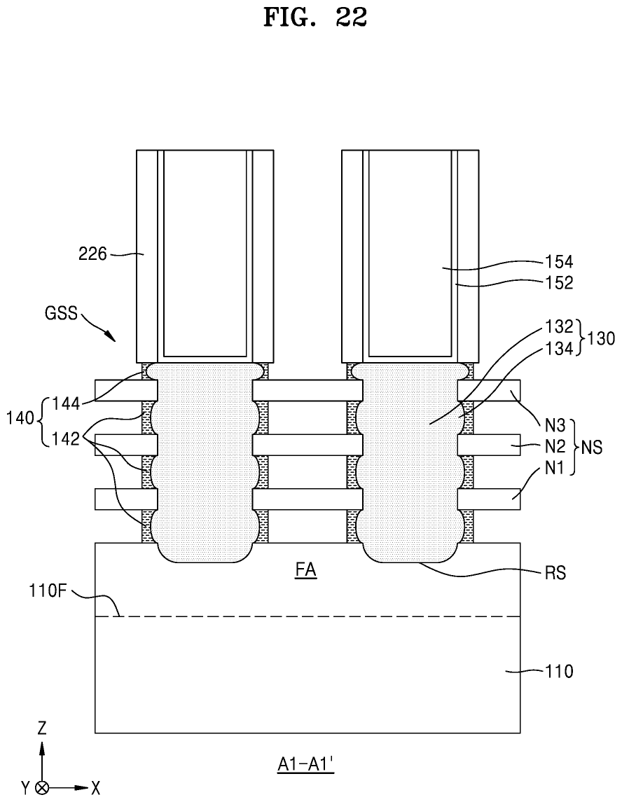

Referring to FIG. 22, in an embodiment, a portion of the spacer forming layer 240 (see FIG. 21) is removed to form the plurality of inner spacers 140.

In some embodiments, the plurality of inner spacers 140 are formed and are in direct contact with the upper surface of the fin-type active region FA, the upper surfaces and the lower surfaces of the plurality of nanosheets NS, and the sidewalls of the inner spacer 140. A process of removing the portion of the spacer forming layer 240 is an etching process that has a selective etching characteristic for the spacer forming layer 240.

Accordingly, cach of the plurality of inner spacers 140 has a first sidewall in direct contact with the source/drain region 130 and an externally exposed second sidewall. The first sidewall of each of the plurality of inner spacers 140 has a recessed curved surface, and the second sidewall thereof has a flat planar surface. For example, the first sidewall of each of the plurality of inner spacers 140 has a recessed shape that corresponds to and is in contact with a protruding source/drain portion 134 of the source/drain region 130.

For example, the plurality of inner spacers 140 include the first inner spacers 142 that are positioned between the plurality of nanosheets NS and on a sidewall of the source/drain region 130, and the second inner spacer 144 disposed on the uppermost layer of the plurality of nanosheets NS and on the sidewall of the source/drain region 130.

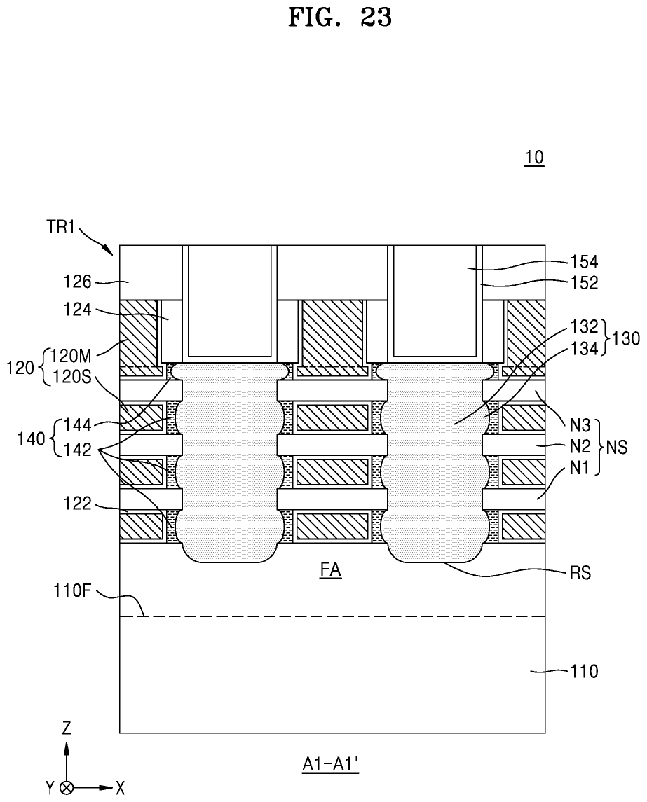

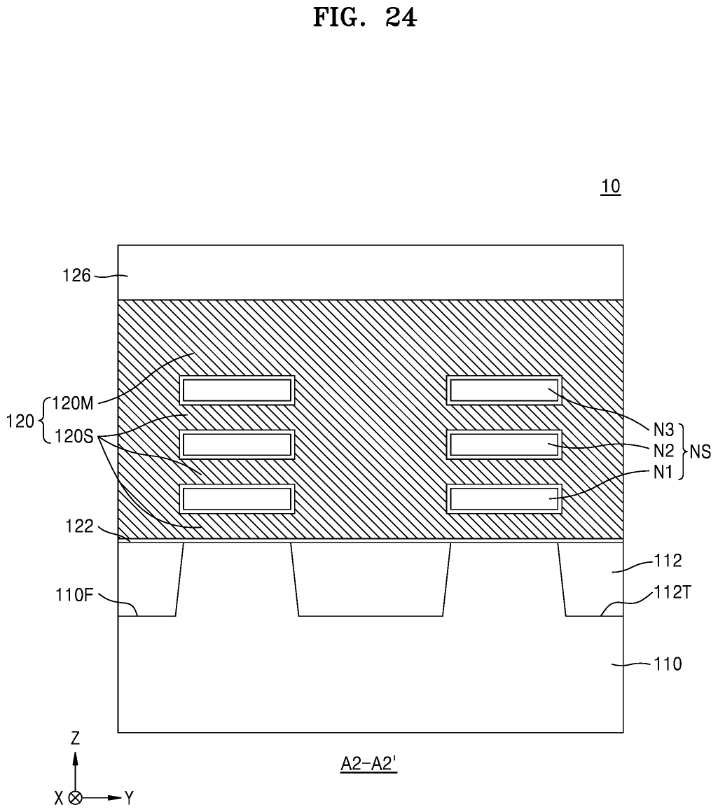

Referring to FIGS. 23 and 24, the gate dielectric layer 122 is formed on exposed surfaces of the gate space GSS.

The gate line 120 that fills the gate space GSS is formed on the gate dielectric layer 122. For example, the gate space GSS is filled by conformally forming a work function conductive layer on the inner wall of the gate space GSS and then forming a buried conductive layer on the work function conductive layer.

The gate line 120 is formed by planarizing the top of the buried conductive layer so that the upper surface of the inter-gate insulating layer 154 is exposed.

Upper portions of the gate line 120, the gate dielectric layer 122, and the sacrificial gate spacer 226 are removed, and the gate capping layer 126 is formed at an upper side of the gate space GSS. The remaining portion of the sacrificial gate spacer 226 may be referred to as the outer spacer 124.

In the integrated circuit device 10 according to an embodiment of the inventive concept that is formed by an above-described manufacturing process, the shapes of the first inner spacers 142 that face the sub-gate portions 120S are differently implemented from the shape of the second inner spacer 144 that face the lower region 120L of the main gate portion 120M, thereby providing stable performance and increased reliability in a nanosheet FET.

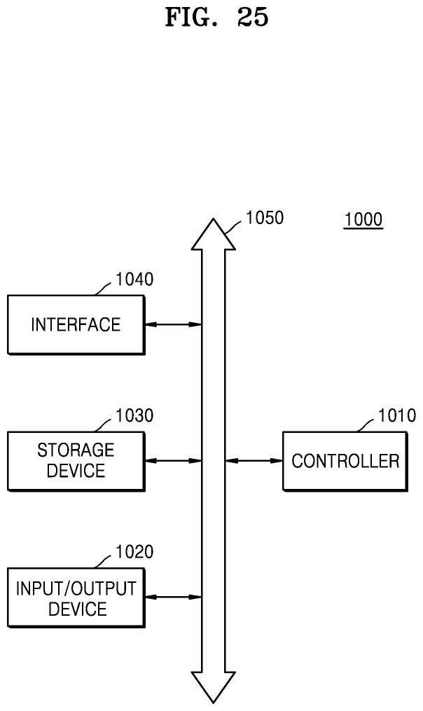

FIG. 25 is a block diagram of a system 1000 that includes an integrated circuit device, according to an embodiment.

Referring to FIG. 25, in an embodiment, the system 1000 includes a controller 1010, an input/output device 1020, a storage device 1030, an interface 1040, and a bus 1050.

The system 1000 may be a mobile system or a system that transmits or receives information. In some embodiments, the mobile system includes one or more of a portable computer, a web tablet, a mobile phone, a digital music player, or a memory card.

The controller 1010 controls an execution program in the system 1000 and includes at least one of a microprocessor, a digital signal processor, or a microcontroller, etc.

The input/output device 1020 inputs or outputs data of the system 1000. The system 1000 can be connected to an external device, such as a personal computer or a network, by using the input/output device 1020, and exchanges data with the external device through the input/output device 1020. The input/output device 1020 includes, for example, one or more of a touch screen, a touch pad, a keyboard, or a display.

The storage device 1030 stores data for operating the controller 1010 or data processed by the controller 1010. The storage device 1030 includes at least one of the integrated circuit devices 10, 20, 30, 40, or 50 according to embodiments of the technical idea of the inventive concept described above.

The interface 1040 provides a data transmission path between the system 1000 and the external device. The controller 1010, the input/output device 1020, the storage device 1030, and the interface 1040 communicate with each other through the bus 1050.

While embodiments of the inventive concept has been particularly shown and described with reference to the accompanying drawings, it will be understood that various changes in form and details may be made therein without departing from the spirit and scope of the following claims.

What is claimed is:

1. An integrated circuit device, comprising:
a fin-type active region that protrudes from a substrate and extends in a first horizontal direction;
a plurality of nanosheets disposed on the fin-type active region and that are separated from each other in a vertical direction;
a gate line that extends in a second horizontal direction perpendicular to the first horizontal direction and surrounds the plurality of nanosheets on the fin-type active region, wherein the gate line includes sub-gate portions interposed between the plurality of nanosheets and a main gate portion disposed above the uppermost layer of the plurality of nanosheets;
a source/drain region disposed on the fin-type active region, adjacent to the gate line, and connected to the plurality of nanosheets; and
a plurality of inner spacers interposed between the gate line and the source/drain region,
wherein shapes of first inner spacers that face the sub-gate portions differ from a shape of a second inner spacer that faces the main gate portion.

2. The integrated circuit device of claim 1, wherein
the main gate portion has an inverted T shape in which a horizontal width of a lower region is greater than a horizontal width of an upper region,
the second inner spacer is disposed on a sidewall of the lower region of the main gate portion, and
the integrated circuit device further includes an outer spacer disposed on a sidewall of the upper region of the main gate portion.

3. The integrated circuit device of claim 2, wherein
a thickness of the lower region of the main gate portion in the vertical direction is less than a thickness of each of the sub-gate portions in the vertical direction, and
a horizontal width of the lower region of the main gate portion is substantially the same as a horizontal width of each of the sub-gate portions.

4. The integrated circuit device of claim 2, wherein the plurality of inner spacers overlap the outer spacer in the vertical direction.

5. The integrated circuit device of claim 1, wherein
a thickness of each of the first inner spacers in the vertical direction is greater than a thickness of the second inner spacer in the vertical direction, and
a width of a central portion of each of the first inner spacers in the first horizontal direction is greater than a width of a central portion of the second inner spacer in the first horizontal direction.

6. The integrated circuit device of claim 1, wherein
a thickness of each of the first inner spacers in the vertical direction is greater than a thickness of the second inner spacer in the vertical direction,
each of the first inner spacers includes an outer wall with a recessed central portion, and
the second inner spacer includes a flat outer wall.

7. The integrated circuit device of claim 1, wherein
a thickness of each of the first inner spacers in the vertical direction is greater than a thickness of the second inner spacer in the vertical direction,
each of the first inner spacers and the second inner spacer includes an outer wall with a recessed central portion,
widths of the top and the bottom of each of the first inner spacers in the first horizontal direction are substantially the same as each other, and
widths of the top and the bottom of the second inner spacer in the first horizontal direction differ from each other.

8. The integrated circuit device of claim 1, further comprising a gate dielectric layer that surrounds the gate line,
wherein a shape of a first gate dielectric layer adjacent to each of the first inner spacers differs from a shape of a second gate dielectric layer adjacent to the second inner spacer.

9. The integrated circuit device of claim 8, wherein
the first gate dielectric layer includes a flat outer wall, and
the second gate dielectric layer includes an outer wall with a pitted central portion.

10. The integrated circuit device of claim 1, wherein the plurality of nanosheets comprise three layers, and the plurality of inner spacers comprise four layers.

11. An integrated circuit device, comprising:
a fin-type active region that protrudes from a substrate and extends in a first horizontal direction;
a plurality of nanosheets disposed on the fin-type active region and separated from each other in a vertical direction;
a gate line that extends in a second horizontal direction perpendicular to the first horizontal direction and surrounds the plurality of nanosheets on the fin-type active region, wherein the gate line includes sub-gate portions interposed between the plurality of nanosheets and a main gate portion disposed above the uppermost layer of the plurality of nanosheets;
a source/drain region disposed on the fin-type active region, adjacent to the gate line, and connected to the plurality of nanosheets;
a plurality of inner spacers interposed between the gate line and the source/drain region; and,
an outer spacer,
wherein the main gate portion has an inverted T shape in which a horizontal width of a lower region is greater than a horizontal width of an upper region, no inner spacer is disposed on a sidewall of the lower region of the main gate portion, and the outer spacer is disposed on a sidewall of the upper region of the main gate portion.

12. The integrated circuit device of claim 11, further comprising a gate dielectric layer that surrounds the gate line,
wherein a shape of a first gate dielectric layer located at each of the sub-gate portions differs from a shape of a second gate dielectric layer located at the lower region of the main gate portion.

13. The integrated circuit device of claim 12, wherein
the first gate dielectric layer includes a flat outer wall, and
the second gate dielectric layer includes an outer wall with a recessed central portion.

14. The integrated circuit device of claim 11, wherein
the plurality of inner spacers overlap the outer spacer in the vertical direction,
each of the plurality of inner spacers includes an outer wall with a recessed central portion, and
the outer spacer includes a flat outer wall.

15. The integrated circuit device of claim 11, wherein
a thickness of the lower region of the main gate portion in the vertical direction is less than a thickness of each of the sub-gate portions in the vertical direction, and
a horizontal width of the lower region of the main gate portion is greater than a horizontal width of each of the sub-gate portions.

16. An integrated circuit device, comprising:
a fin-type active region that protrude from a substrate and extend in a first horizontal direction;
a plurality of nanosheet layers disposed on the fin-type active region and separated from each other in a vertical direction;
a gate line that extends in a second horizontal direction perpendicular to the first horizontal direction and surrounds the plurality of nanosheet layers on the fin-type active region, wherein the gate line includes sub-gate portions interposed between the plurality of nanosheet layers and a main gate portion disposed above the uppermost layer of the plurality of nanosheet layers;
a source/drain region disposed on the fin-type active region, adjacent to the gate line, and connected to the plurality of nanosheet layers;
an inter-gate insulating layer disposed adjacent to the gate line on the source/drain region;
a plurality of inner spacer layers that include first inner spacers interposed between the sub-gate portions and the source/drain region and a second inner spacer interposed between a lower region of the main gate portion and the source/drain region;
an outer spacer interposed between an upper region of the main gate portion and the inter-gate insulating layer; and
a gate dielectric layer that surrounds the gate line,
wherein shapes of the first inner spacers that face the sub-gate portions between the plurality of nanosheet layers differ from a shape of a second inner spacer that faces the lower region of the main gate portion.

17. The integrated circuit device of claim 16, wherein
the main gate portion has an inverted T shape in which a horizontal width of the lower region is greater than a horizontal width of the upper region,
a thickness of the lower region of the main gate portion in the vertical direction is less than a thickness of each of the sub-gate portions in the vertical direction, and
a horizontal width of the lower region of the main gate portion is substantially the same as a horizontal width of each of the sub-gate portions.

18. The integrated circuit device of claim 16, wherein
a thickness of each of the first inner spacers in the vertical direction is greater than a thickness of the second inner spacer in the vertical direction, and
a width of a central portion of each of the first inner spacers in the first horizontal direction is greater than a width of a central portion of the second inner spacer in the first horizontal direction.

19. The integrated circuit device of claim 16, wherein the second inner spacer is disposed on the uppermost layer of the plurality of layers of nanosheets.

20. The integrated circuit device of claim 19, wherein
the lower surface of the second inner spacer is in contact with the uppermost layer of the plurality of nanosheet layers, and the upper surface of the second inner spacer is in contact with the lower surface of the outer spacer.
